(19) United States
(12) Patent Application Publication
(10) Pub. No.: US 2006/0172556 A1
(43) Pub. Date: Aug. 3, 2006

(54) Semiconductor device having a high carbon content strain inducing film and a method of manufacture therefor

(75) Inventors: Wayne A. Bather, Richardson, TX (US); Narendra S. Mehta, Dallas, TX (US); Troy Yocum, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/344,998

(22) Filed: Feb. 1, 2006

Related U.S. Application Data
(60) Provisional application No. 60/649,019, filed on Feb. 1, 2005.

(51) Int. Cl. H01L 21/31; H01L 21/469

(52) U.S. Cl. 438/794

(57) ABSTRACT

The present invention provides a method for manufacturing a semiconductor device as well as a semiconductor device. The method, among other steps, may include forming a gate structure (230) over a substrate (210), and forming a strain inducing film (330, 520, 530 or 810) over the substrate (210) and proximate the gate structure (230), the strain inducing film (330, 520, 530 or 810) comprising a bis t-butylaminosilane (BTBAS) silicon nitride layer formed using ratio of bis t-butylaminosilane (BTBAS) to ammonia (NH₃) of 1:1 or greater.

### CROSS-REFERENCE TO PROVISIONAL APPLICATION

This application claims the benefit of U.S. Provisional Application No. 60/649,019 entitled “ENHANCING DOSE RETENTION IN ACTIVE REGION OF TRANSISTORS BY INDUCING STRAIN 1N SILICON BY VARYING CARBON CONTENT 1N SiN FILMS,” to Wayne Bather, et al., filed on Feb. 1, 2005, which is commonly assigned with the present invention and incorporated herein by reference as if reproduced herein in its entirety.

### TECHNICAL FIELD OF THE INVENTION

The present invention is directed, in general, to a semiconductor device and, more specifically, to a semiconductor device having a high carbon content strain inducing film and a method of manufacture therefore.

### BACKGROUND OF THE INVENTION

There exists a continuing need to improve semiconductor device performance and further scale semiconductor devices. A characteristic that limits scalability and device performance is electron and hole mobility, also referred to as channel mobility, throughout the channel region of transistors. As devices continue to shrink in size, the channel region for transistors continues to also shrink in size, which can limit channel mobility.

One technique that may improve scaling limits and device performance is to introduce strain into the channel region, which can improve electron and hole mobility. Different types of strain, including expansive strain, uniaxial tensile strain, and compressive strain, have been introduced into channel regions of various types of transistors in order to determine their effect on electron and/or hole mobility. For some devices, certain types of strain improve mobility whereas other types degrade mobility.

Turning briefly to FIG. 1 illustrated is a sectional view of a semiconductor device 100 at a stage of fabrication wherein a tensile strain is introduced by a silicon nitride cap-annealing process. The semiconductor device 100, which happens to be an n-channel metal oxide semiconductor (NMOS) device, includes a substrate 110 having a well region 120 located therein. The semiconductor device 100 of FIG. 1 further includes a gate structure 130 located over the substrate 110. The gate structure 130, as appreciated, includes both a gate dielectric layer 133 and a gate electrode layer 138.

Positioned on both sides of the gate structure 130 are source/drain sidewall spacers 140. The source/drain sidewall spacers 140 illustrated in FIG. 1 each include only a single sidewall spacer. Those skilled in the art understand, however, that various other types of spacers, including offset spacers, L-shaped spacers and others could nevertheless be used. Positioned in the substrate 110 proximate the gate structure 130 are source/drain regions 150. The source/drain regions 150 therefore define a channel region 160 in the substrate 110.

After the source/drain regions 150 have been formed by implanting a suitable dopant, such as arsenic in the instant case, a strain-inducing layer 170 is deposited over the substrate 110 and gate structure 130. Among other processes, a chemical vapor deposition (CVD) process could be used to form the strain-inducing layer 170. Then, a rapid thermal anneal is performed at a relatively high temperature, introducing and locking strain 180 into the channel region 160. The strain-inducing layer 170 is then removed and silicide regions (not shown) are typically formed on the source/drain regions 150 and gate electrode layer 138. A suitable silicide process is a conventional cobalt, nickel or other similar metal salicide process.

Compressive stress from the gate electrode layer 138 is enhanced by the annealing process described above, which introduces tensile strain 180 across the channel region 160. This tensile strain 180 can improve the performance of the semiconductor device 100 by improving hole and electron mobility in the channel region 160. The cap-annealing process described supra can show improvement for, among others, NMOS devices. Unfortunately, it has been observed that the introduction of strain into the channel region 160 using conventional strain-inducing layers, alone, is insufficient to support some of the next generation devices.

Accordingly, what is needed in the art is an improved method for manufacturing a semiconductor device, and a device manufactured using that method, which provides improved channel mobility.

### SUMMARY OF THE INVENTION

To address the above-discussed deficiencies of the prior art, the present invention provides a method for manufacturing a semiconductor device as well as a semiconductor device. The method, among other steps, may include forming a gate structure over a substrate, and forming a strain inducing film over the substrate and proximate the gate structure, the strain inducing film comprising a bis t-butylaminosilane (BTBAS) silicon nitride layer formed using ratio of bis t-butylaminosilane (BTBAS) to ammonia (NH₃) of 1:1 or greater.

The present invention further provides a semiconductor device. The semiconductor device, without limitation, may include a gate structure located over a substrate, and a strain inducing film located over the substrate and proximate the gate structure, the strain inducing film comprising a bis t-butylaminosilane (BTBAS) silicon nitride layer having a peak carbon concentration of about 1.1E21 atoms/cm³ or greater.

### BRIEF DESCRIPTION OF THE DRAWINGS

For a more complete understanding of the present invention, reference is now made to the following descriptions taken in conjunction with the accompanying drawings, in which:

Prior Art FIG. 1 illustrates a sectional view of a semiconductor device at a stage of fabrication wherein a compressive strain is introduced by a conventional cap-annealing process;

FIGS. 2-9 illustrate sectional views of detailed manufacturing steps illustrating how one might manufacture a semiconductor device in accordance with the principles of the present invention; and

FIG. 10 illustrates a sectional view of an integrated circuit (IC) incorporating a semiconductor device constructed according to the principles of the present invention.

### DETAILED DESCRIPTION

The present invention is based, at least in part, on the recognition that conventional bis t-butylaminosilane (BTBAS) silicon nitride layers are generally unable to provide the desired amount of silicon strain to accommodate today's semiconductor devices. Without being limited to such, the present invention believes that the limited strain is at least partially due to the low carbon content of the conventional BTBAS silicon nitride layers. For instance, conventional BTBAS silicon nitride layers have a peak carbon concentration of 1.0E21 atoms/cm³ or less, such a carbon concentration believed to limit the stress therein, and thus limit the strain in the underlying silicon.

Based on the aforementioned recognition, the present invention has acknowledged that by increasing the ratio of BTBAS to ammonia (NH₃) during the formation of the silicon nitride layer to a value of 1:1 or greater, the carbon concentration in the BTBAS silicon nitride layer can be increased. As the carbon concentration in the BTBAS silicon nitride layer is increased, the stress therein is also increased, thereby increasing the strain in the underlying silicon. For example, the present invention has conducted many different experiments and determined that such a BTBAS to ammonia ratio can provide a peak carbon concentration of about 1.1E21 atoms/cm³ or greater, or even 2.0E21 atoms/cm³ or greater, resulting in a stress value of 1.25 GPa or greater. The present invention has further acknowledged that the increase in stress in the BTBAS silicon nitride layer also increases the resulting boron concentration in the substrate of the semiconductor device (e.g., for a given original boron dose and concentration), which further results in less source/drain resistance and increased transistor performance. Specifically, it is believed that the higher stress in the BTBAS silicon nitride layer reduces the boron outdiffusion from the substrate.

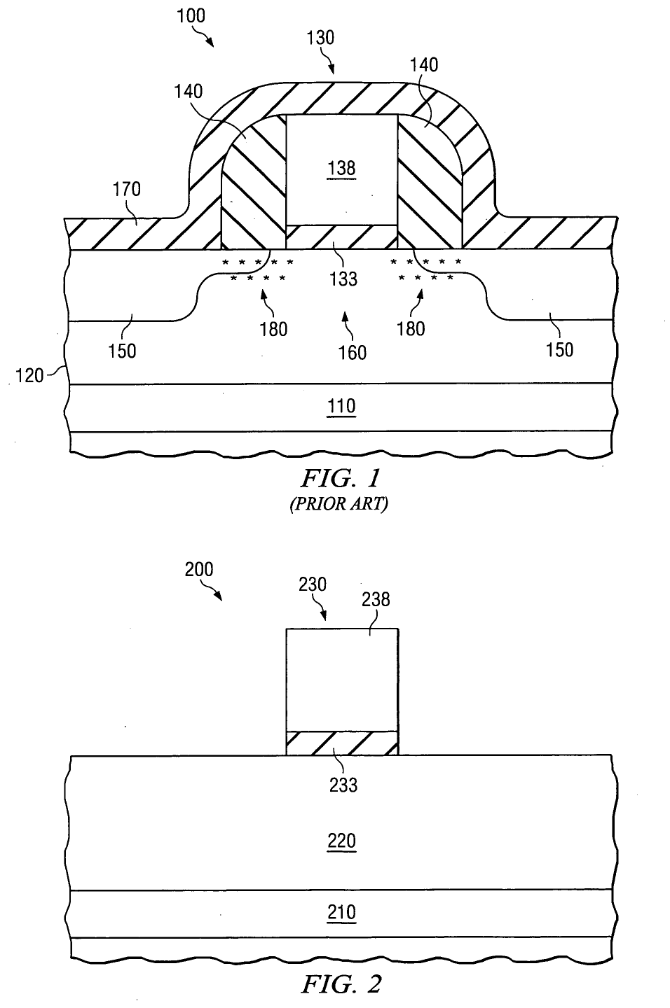

Turning now to FIGS. 2-9, illustrated are cross-sectional views of detailed manufacturing steps illustrating how one might manufacture a semiconductor device in accordance with the principles of the present invention. FIG. 2 illustrates a sectional view of a partially completed semiconductor device 200 at an initial stage of manufacture. From the outset, it should be noted that the embodiment of FIGS. 2-9 will be discussed as an n-channel metal oxide semiconductor (NMOS) device. In an alternative embodiment, all the dopant types, except for possibly the substrate dopant, could be reversed, resulting in a p-channel metal oxide semiconductor (PMOS) device. However, at least with regard to FIGS. 2-9, no further reference to this opposite scheme will be discussed.

In the advantageous embodiment shown, the semiconductor device 200 of FIG. 2 includes a substrate 210. The substrate 210 may, in an illustrative embodiment, be any layer located in the semiconductor device 200, including a wafer itself or a layer located above the wafer (e.g., epitaxial layer). In the embodiment illustrated in FIG. 2, the substrate 210 is a P-type substrate; however, one skilled in the art understands that the substrate 210 could also be an N-type substrate.

Located within the substrate 210 is a well region 220. The well region 220 contains a P-type dopant. For example, the well region 220 would likely be doped with a P-type dopant dose ranging from about 1E13 atoms/cm² to about 1E14 atoms/cm² and at an energy ranging from about 100 keV to about 500 keV. This may result in the well region 220 having a peak dopant concentration ranging from about 5E17 atoms/cm³ to about 1E19 atoms/cm³. Those skilled in the art understand that in certain circumstances where the P-type substrate 210 dopant concentration is high enough, the well region 220 may be excluded.

Located over the substrate 210 is a gate structure 230. The gate structure 230 includes a gate dielectric 233 and a gate electrode 238. The gate dielectric 233 may comprise a number of different materials and stay within the scope of the present invention. For example, the gate dielectric 233 may comprise silicon dioxide, or in an alternative embodiment comprise a high dielectric constant (K) material. In the illustrative embodiment of FIG. 2, however, the gate dielectric 233 is a silicon dioxide layer having a thickness ranging from about 0.5 nm to about 5 nm.

Any one of a plurality of manufacturing techniques could be used to form the gate dielectric 233. For example, the gate dielectric 233 may be either grown or deposited. Additionally, the growth or deposition steps may require a significant number of different temperatures, pressures, gasses, flow rates, etc.

While the advantageous embodiment of FIG. 2 discloses that the gate electrode 238 comprises standard polysilicon, other embodiments exist where the gate electrode 238, or at least a portion thereof, comprises amorphous polysilicon material, a metal material, or fully silicided metal material. The amorphous polysilicon embodiment may be particularly useful when a substantially planar upper surface of the gate electrode 238 is desired.

The deposition conditions for the gate electrode 238 may vary. However, if the gate electrode 238 were to comprise standard polysilicon, such as the instance in FIG. 2, the gate electrode 238 could be deposited using a pressure ranging from about 100 torr to about 0.300 torr, a temperature ranging from about 620° C. to about 700° C., and a SiH₄ or Si₂H₆ gas flow ranging from about 50 sccm to about 150 sccm. If, however, amorphous polysilicon were desired, the amorphous polysilicon gate electrode could be deposited using a pressure ranging from about 100 torr to about 300 torr, a temperature ranging from about 450° C. to about 550° C., and a SiH₄ or Si₂H₆ gas flow ranging from about 100 sccm to about 300 sccm. In any instance, the gate electrode 238 desirably has a thickness ranging from about 50 nm to about 150 nm.

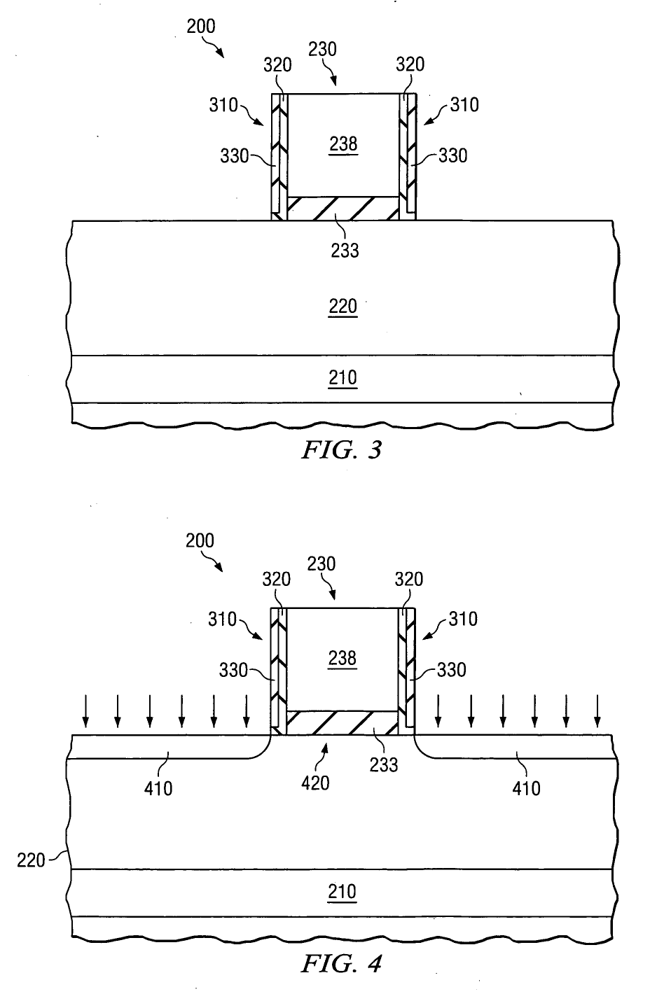

Turning briefly to FIG. 3 illustrated is a sectional view of the semiconductor device 200 of FIG. 2 after formation of portions of gate sidewall spacers 310. The portions of the gate sidewall spacers 310 shown in FIG. 3 include an oxide layer 320 and a BTBAS silicon nitride layer 330. The BTBAS silicon nitride layer 330, in the embodiment of FIG. 3, functions as a sidewall nitride spacer as well as a strain inducing film. The oxide layer 320, as compared to similar layers used in the prior art, may be formed at least partially using a deposition process. In an optional process, the oxide layer 320 is initially formed using a first deposition process, and then finished using a second oxidation process. The first deposition process allows the oxide layer 320 to form on the top and sidewalls of the gate structure 230 when they do not comprise silicon. In an alternative embodiment, the entire oxide layer 320 is either grown or deposited.

The BTBAS silicon nitride layer 330, which as previously discussed may function as a sidewall offset nitride spacer as well as a strain inducing film, would typically comprise a high carbon content strain inducing film. For instance, the BTBAS silicon nitride layer 330 should typically have a peak carbon concentration of about 1.1E21 atoms/cm³ or greater. In an alternative embodiment, the BTBAS silicon nitride layer 330 could have a peak carbon concentration of about 1.5E21 atoms/cm³ or greater, or even a peak carbon concentration of about 2.0E21 atoms/cm³ or greater. What results with such peak carbon concentrations is the BTBAS silicon nitride layer 330 having a stress value of 1.25 GPa or greater. In one embodiment the BTBAS silicon nitride layer 330 might even have a stress value of 2.25 GPa or greater.

The BTBAS silicon nitride layer 330 would typically be deposited using a chemical vapor deposition (CVD) process to a thickness ranging from about 1 nm to about 50 nm. In the specific embodiment shown in FIG. 3, the BTBAS silicon nitride layer 330 would typically be deposited using a non-plasma CVD process to a thickness ranging from about 2.0 nm to about 10 nm. The BTBAS silicon nitride layer 330, as compared to conventional BTBAS silicon nitride layers, may be formed using a ratio of BTBAS to ammonia (NH₃) of about 1:1 or greater. In other embodiments, however, the BTBAS silicon nitride layer 330 is formed using a ratio of BTBAS to ammonia (NH₃) of about 2:1 or greater, or even 4:1 or greater, depending on the desired amount of carbon. The temperature maintained during the formation of the BTBAS silicon nitride layer 330 should remain relatively low, for example a temperature of less than about 600° C. In an alternative embodiment, the temperature remains between about 500° C. and about 550° C. Likewise, the pressure used during the formation of the BTBAS silicon nitride layer 330 would desirably range from about 100 mTorr to about 1 Torr.

While the oxide layer 320 and the BTBAS silicon nitride layer 330 are shown located only along the sides of the gate structure 230, those skilled in the art are aware that the layers may have been previously blanket formed and subsequently anisotropically etched to form the oxide layer 320 and the BTBAS silicon nitride layer 330. It should be noted that certain embodiments may exist where the blanket oxide layer 320 and blanket BTBAS silicon nitride layer 330 would remain at this point and not be anisotropically etched as shown in FIG. 3. One skilled in the art understands that the embodiment of FIG. 3 is just an illustrative embodiment and that the oxide layer 320 and the BTBAS silicon nitride layer 330 could be formed after the source/drain extension implants 410 (FIG. 4).

Turning now to FIG. 4, illustrated is a sectional view of the semiconductor device 200 of FIG. 3 after formation of source/drain extension implants 410 within the substrate 210. The source/drain extension implants 410 may be conventionally formed and generally have a peak dopant concentration ranging from about 1E19 atoms/cm³ to about 2E20 atoms/cm³. As is standard in the industry, the source/drain extension implants 410 have a dopant type opposite to that of the well region 220 they are located within. Accordingly, the source/drain extension implants 410 are doped with an N-type dopant, thereby forming a channel region 420.

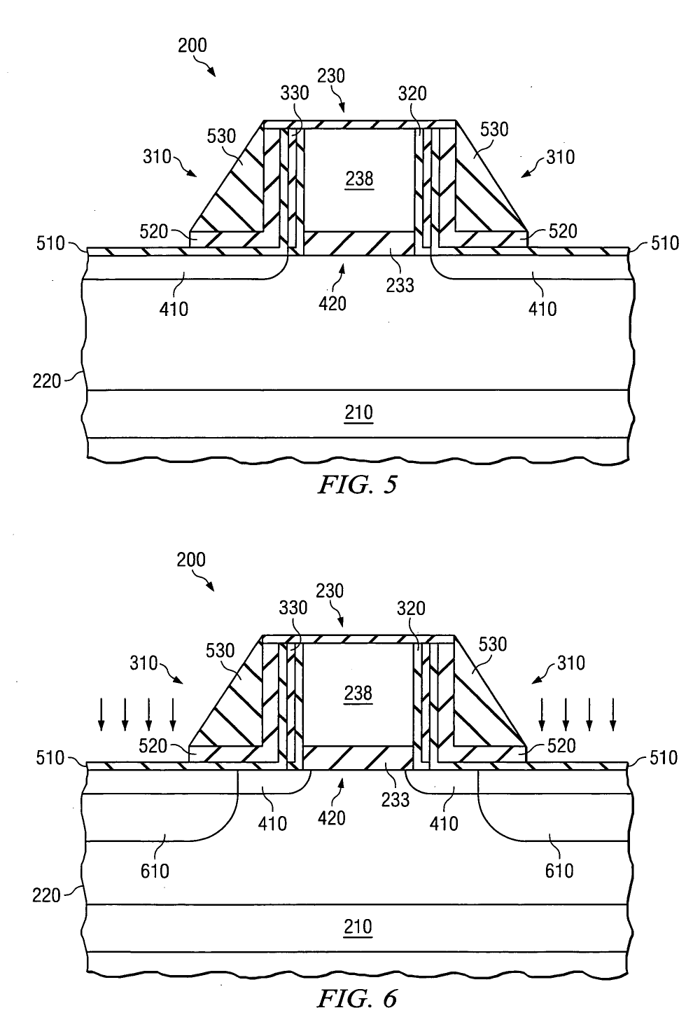

Turning now to FIG. 5, illustrated is a sectional view of the semiconductor device 200 illustrated in FIG. 4 after forming additional portions of the gate sidewall spacers 310. Particularly, a cap oxide 510, L-shaped spacers 520 and offset spacers 530 complete the gate sidewall spacers 310. The cap oxide 510, among other purposes, has the job of preventing the L-shaped spacers 520 from directly contacting the substrate 210. Most likely, the cap oxide 510 will be deposited over the semiconductor device 200 using a process similar to that used to form the oxide layer 320. In an alternative embodiment, not shown, the cap oxide 510 is removed from a region above the source/drain extension implants 410.

The L-shaped spacers 520 may comprise many different types of materials. However, in another embodiment the L-shaped spacers 520 comprise a BTBAS silicon nitride layer. For example, the L-shaped spacers 520 might comprise the same material as the previously discussed BTBAS silicon nitride layer 330. Accordingly, the L-shaped spacers 520, when comprising the BTBAS silicon nitride layer, could also function as a strain inducing film. In this embodiment, the L-shaped spacers 520 comprising the BTBAS silicon nitride film could be manufactured using a process similar to that disclosed above with respect to the BTBAS silicon nitride layer 330. In an alternative embodiment of the present invention, the L-shaped spacers 520 would comprise the BTBAS silicon nitride film having the high concentration of carbon, and the feature 330 would not. In this embodiment the feature 330 might comprise a conventional silicon nitride, or other similar layer.

The offset spacers 530 that are located over the L-shaped spacers 520 may additionally comprise the BTBAS silicon nitride layer. In the embodiment wherein the offset spacers 530 comprise the BTBAS silicon nitride layer, the offset spacers 530 might also function as a strain inducing film. Typically, the layers of the gate sidewall spacers 310 will alternate between an oxide and a nitride. Accordingly, two films comprising the BTBAS silicon nitride layer will not generally be located on one another. For example, in the embodiment shown in FIG. 5, it is most likely that one or both of features 330 and 520 would comprise the BTBAS silicon nitride layer manufactured in accordance with the principles of the present invention, and that features 320, 510 and 530 would comprise conventional oxides. However, another embodiment might exist wherein features 330 and 520 would comprise conventional oxides, and one or all of features 320, 510 and 530 would comprise the BTBAS silicon nitride layer manufactured in accordance with the principles of the present invention. Accordingly, the present invention should not be limited to any specific location or orientation for the BTBAS silicon nitride layer.

Thus, while a substantial amount of detail has been given regarding the specifics of the gate sidewall spacers 310, such should not be construed to be limiting on the present invention. For example, certain embodiments exist where only the offset spacer 330 and sidewall oxides 530, or another similar structure, comprise the gate sidewall spacers 310. Other embodiments exist where all the layers shown in FIG. 5 exist, however, the materials and thicknesses are different. In another embodiment of the invention, the material chosen for the gate sidewall spacers 310 is based on its disposable nature. Therefore, as previously noted, the details given with respect to FIGS. 3 and 5 regarding the gate sidewall spacers should not be used to limit the scope of the present invention.

Turning now to FIG. 6, illustrated is a sectional view of the semiconductor device 200 of FIG. 5 after the formation of highly doped source/drain implants 610 within the substrate 210. Those skilled in the art understand that conventional processes could be used to form the highly doped source/drain implants 610. Generally, the highly doped source/drain implants 610 have a peak dopant concentration ranging from about 1E18 atoms/cm³ to about 1E21 atoms/cm³. Also, the highly doped source/drain implants 610 should typically have a dopant type opposite to that of the well region 220 they are located within. Accordingly, in the illustrative embodiment shown in FIG. 6, the highly doped source/drain implants 610 are doped with an N-type dopant.

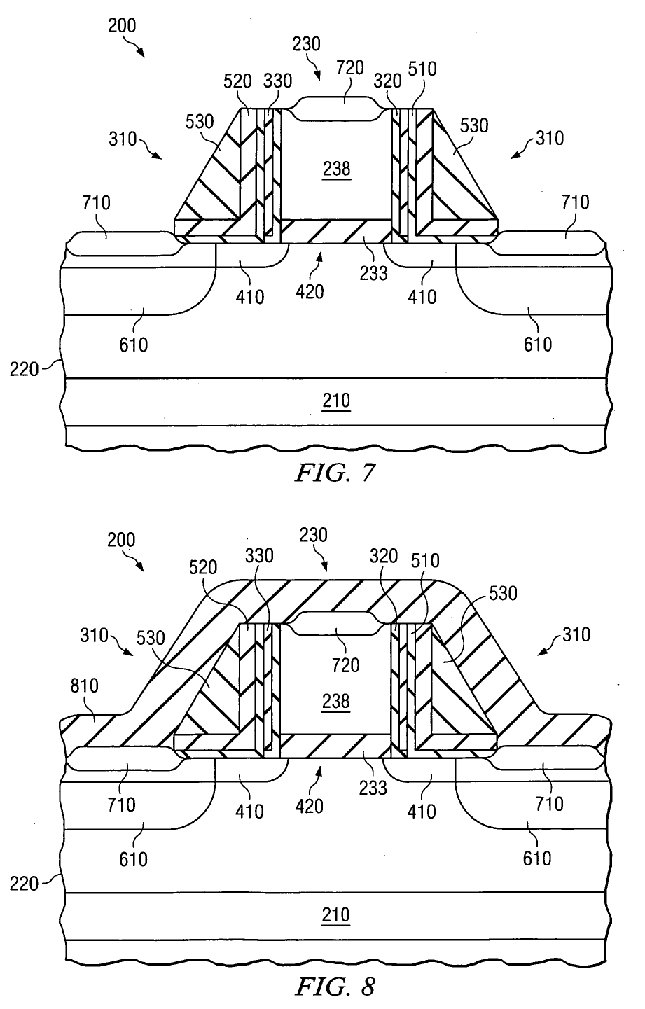

Turning now to FIG. 7, illustrated is a sectional view of the semiconductor device 200 of FIG. 6 after forming silicided source/drain regions 710 and a silicided gate electrode layer 720. The skilled artisan understands the silicided source/drain region 710 and silicided gate electrode layer 720 formation process. In sum, the process may include forming a metal layer, possibly cobalt, nickel, etc., over the substrate 210 and gate structure 230, and subjecting the metal layer to an anneal, causing the metal to react with the silicon of the substrate 210, and in this instance the gate electrode layer 238, and form the silicided source/drain regions 710 and silicided gate electrode layer 720.

Turning now to FIG. 8, illustrated is a sectional view of the semiconductor device 200 of FIG. 7 after forming a capping layer 810 over the gate structure 230 and substrate 210. The capping layer 810, in one embodiment of the present invention, comprises a BTBAS silicon nitride layer formed in accordance with the principles of the present invention. Accordingly, the capping layer 810 might comprise a high carbon concentration BTBAS silicon nitride layer, and thus also function as a strain inducing film. In the embodiment wherein the capping layer 810 comprises a BTBAS silicon nitride layer, the capping layer 810 might be manufactured using the same process as disclosed above with respect to the BTBAS silicon nitride layer 330. In an alternative embodiment, the capping layer 810 might be the only feature in the semiconductor device 200 to comprise the BTBAS silicon nitride layer manufactured in accordance with the principles of the present invention. Likewise, two or more features of the semiconductor device 200 could comprise such a BTBAS silicon nitride layer. It should be noted that if the capping layer 810 were not to comprise the BTBAS silicon nitride layer, it might comprise a conventional silicon nitride film.

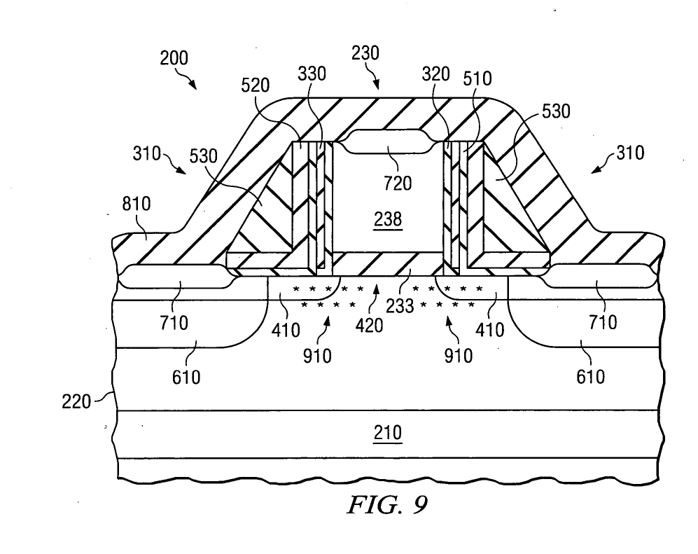

Turning now to FIG. 9, illustrated is a sectional view of the semiconductor device 200 of FIG. 8 after subjecting the capping layer 810 to a thermal anneal. In the embodiment shown, the thermal anneal imparts a strain 910 into the substrate 210, particularly the channel region 420. The thermal anneal, which happens to be a rapid thermal anneal in the illustrative embodiment of FIG. 9, is typically performed at a temperature of greater than about 350° C., and less than about 800° C., for a time period of less than about 180 seconds. The selection of the anneal temperature should be compatible with the chosen silicide material, to avoid degradation in silicide conductivity.

It should be noted that FIGS. 7-9 illustrate that the silicided source/drain regions 710 and a silicided gate electrode layer 720 are formed prior to the formation of the capping layer 810 and anneal thereof. However, another embodiment exists wherein the capping layer 810 is formed, annealed to lock in the strain in the substrate 210, subsequently removed, and after its removal the silicided source/drain regions 710 and a silicided gate electrode layer 720 are formed. Accordingly, the present invention should not be limited to any specific order in the formation of the silicided source/drain regions 710 and a silicided gate electrode layer 720 and capping layer 810.

The semiconductor device 200 resulting after the anneal of FIG. 9 has a number of benefits over conventional devices. One such benefit is the increased strain that results in the channel region 420 as a result of the use of one or more high carbon concentration BTBAS silicon nitride layers. Another benefit is the increased boron concentration in the channel region 420, and thus decreased resistance therein, that results from the higher stress high carbon concentration BTBAS silicon nitride layers. Not only does the resulting semiconductor device 200 benefit from the manufacturing process of the present invention, but existing hardware and processing steps may be used, which reduces the time and cost associated with introducing the novel aspects of the present invention. Likewise, the use of the BTBAS silicon nitride layer allows for a lower thermal budget, at least as compared to other alternatives that do not comprise the BTBAS silicon nitride layer.

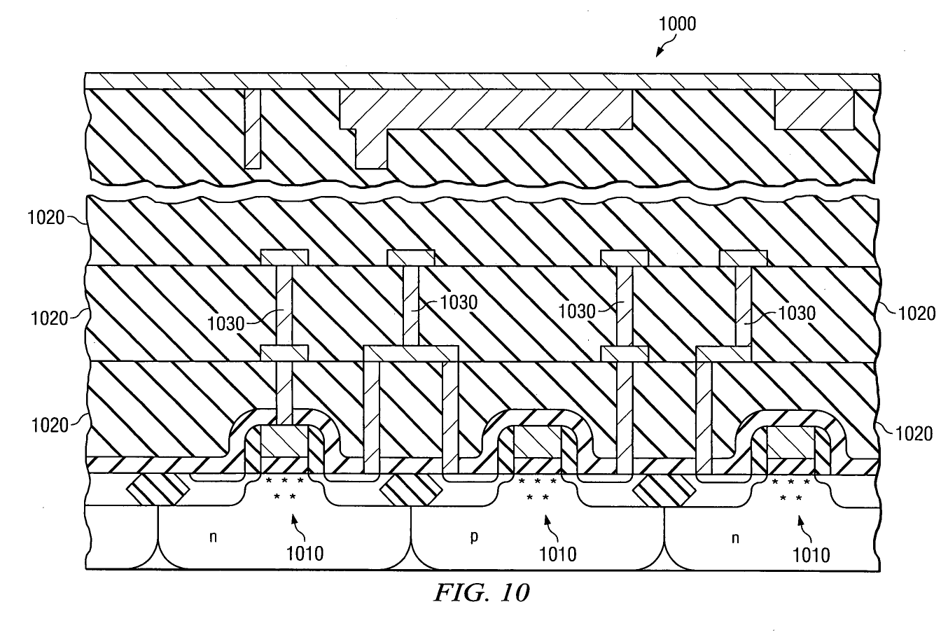

Referring finally to FIG. 10, illustrated is a sectional view of an integrated circuit (IC) 1000 incorporating a semiconductor device 1010 constructed according to the principles of the present invention. The IC 1000 may include devices, such as transistors used to form CMOS devices, BiCMOS devices, Bipolar devices, or other types of devices. The IC 1000 may further include passive devices, such as inductors or resistors, or it may also include optical devices or optoelectronic devices. Those skilled in the art are familiar with these various types of devices and their manufacture. In the particular embodiment illustrated in FIG. 10, the IC 1000 includes semiconductor devices 1010 having dielectric layers 1020 located thereover. Additionally, interconnect structures 1030 are located within the dielectric layers 1020 to interconnect various devices, thus, forming the operational integrated circuit 1000.

Although the present invention has been described in detail, those skilled in the art should understand that they could make various changes or substitutions herein without departing from the spirit and scope of the invention in its broadest form.

What is claimed is:

1. A method for manufacturing a semiconductor device, comprising:
forming a gate structure over a substrate; and
forming a strain inducing film over the substrate and proximate the gate structure, the strain inducing film-comprising a bis t-butylaminosilane (BTBAS) silicon nitride layer formed using ratio of bis t-butylaminosilane (BTBAS) to ammonia (NH₃) of 1:1 or greater.

2. The method as recited in claim 1 wherein forming the strain inducing film includes forming the strain inducing film using a temperature of less than about 600° C.

3. The method as recited in claim 1 wherein the bis t-butylaminosilane (BTBAS) silicon nitride layer has a peak carbon concentration of about 1.1E21 atoms/cm³ or greater.

4. The method as recited in claim 3 wherein the bis t-butylaminosilane (BTBAS) silicon nitride layer has a peak carbon concentration of about 2.0E21 atoms/cm³ or greater.

5. The method as recited in claim 1 wherein the bis t-butylaminosilane (BTBAS) silicon nitride layer has a stress value of about 1.25 GPa or greater.

6. The method as recited in claim 1 wherein the bis t-butylaminosilane (BTBAS) silicon nitride layer has a stress value of about 2.25 GPa or greater.

7. The method as recited in claim 1 wherein the bis t-butylaminosilane (BTBAS) silicon nitride layer is located proximate a sidewall of the gate structure.

8. The method as recited in claim 7 wherein the bis t-butylaminosilane (BTBAS) silicon nitride layer forms at least a portion of a sidewall spacer or offset spacer.

9. The method as recited in claim 1 wherein the bis t-butylaminosilane (BTBAS) silicon nitride layer is formed as a capping layer over the substrate and gate structure.

10. The method as recited in claim 1 further including forming a dielectric layer having one or more interconnects therein over the gate structure, the one or more interconnects contacting the gate structure to form an operational integrated circuit.

11. A semiconductor device, comprising:
a gate structure located over a substrate;
a strain inducing film located over the substrate and proximate the gate structure, the strain inducing film comprising a bis t-butylaminosilane (BTBAS) silicon nitride layer having a peak carbon concentration of about 1.1E21 atoms/cm³ or greater.

12. The semiconductor device as recited in claim 11 wherein the bis t-butylaminosilane (BTBAS) silicon nitride layer has a peak carbon concentration of about 1.5E21 atoms/cm³ or greater

13. The semiconductor device as recited in claim 11 wherein the bis t-butylaminosilane (BTBAS) silicon nitride layer has a peak carbon concentration of about 2.0E21 atoms/cm³ or greater.

14. The semiconductor device as recited in claim 11 wherein the bis t-butylaminosilane (BTBAS) silicon nitride layer has a stress value of about 1.25 GPa or greater.

15. The semiconductor device as recited in claim 11 wherein the bis t-butylaminosilane (BTBAS) silicon nitride layer has a stress value of about 1.75 GPa or greater.

16. The semiconductor device as recited in claim 11 wherein the bis t-butylaminosilane (BTBAS) silicon nitride layer has a stress value of about 2.25 GPa or greater.

17. The semiconductor device as recited in claim 11 wherein the bis t-butylaminosilane (BTBAS) silicon nitride layer is located proximate a sidewall of the gate structure.

18. The semiconductor device as recited in claim 17 wherein the bis t-butylaminosilane (BTBAS) silicon nitride layer forms at least a portion of a sidewall spacer or offset spacer.

19. The semiconductor device as recited in claim 11 wherein the bis t-butylaminosilane (BTBAS) silicon nitride layer is formed as a capping layer over the substrate and gate structure.

20. The semiconductor device as recited in claim 11 further including a dielectric layer having one or more interconnects therein located over the gate structure, the one or more interconnects contacting the gate structure and forming an operational integrated circuit.
